(19) United States
(12) Patent Application Publication
(10) Pub. No.: US 2025/0149815 A1
(43) Pub. Date: May 8, 2025

(54) CONNECTOR AND ELECTRONIC EQUIPMENT

(71) Applicant: Mitsubishi Electric Corporation, Tokyo (JP)

(72) Inventor: Fujiyuki NAKAMOTO, Tokyo (JP)

(73) Assignee: Mitsubishi Electric Corporation, Tokyo (JP)

(21) Appl. No.: 19/011,758

(22) Filed: Jan. 7, 2025

Related U.S. Application Data
(63) Continuation of application No. PCT/JP2022/034492, filed on Sep. 15, 2022.

(51) Int. Cl. H01R 12/75; H01R 13/6464; H01R 13/6471; H01R 13/66

(52) U.S. Cl. CPC H01R 12/75; H01R 13/6464; H01R 13/6471; H01R 13/665

(57) ABSTRACT

A connector includes: a first spring structure having a first end which is connected to a connection part; a second spring structure including a coiled winding which is wound in the same direction as the first spring structure, the second spring structure having a first end which is connected to a connection part; a conductor to electrically connect the first spring structure and the second spring structure; and a bypass capacitor having a first electrode terminal which is connected to the first spring structure and the conductor, and a second electrode terminal which is grounded, and each turn of the winding of the first spring structure and each turn of the winding of the second spring structure are insulated from each other and arranged alternately along the same direction.

### CROSS REFERENCE TO RELATED APPLICATIONS

This application is a Continuation of PCT International Application No. PCT/JP2022/034492 filed on Sep. 15, 2022, all of which is hereby expressly incorporated by reference into the present application.

### TECHNICAL FIELD

The present disclosure relates to a connector and electronic equipment.

### BACKGROUND ART

As a conventional connector that connects between boards included in electronic equipment, there is a connector described in Patent Literature 1, for example. In the connector described in Patent Literature 1, a coiled spring member is disposed in each of two connection objects, and the windings of the two spring members are alternately arranged in the same direction. Because an electrical conduction line is wound around each spring member, the alternate arrangement causes the spring members to get entangled with each other because of the elasticity of the springs, thereby making an electrical connection between the spring members. As a result, the connection objects are electrically connected. Because the two spring members get entangled with each other and are placed in the state in which an electrical connection is established between them, and hence function as a single coiled connection member, the two spring members are equivalent to an inductor disposed in series.

### CITATION LIST

### Patent Literature

Patent Literature 1: JP-A-Hei 10-247568

### SUMMARY OF INVENTION

### Technical Problem

However, because the filter performance of a series inductor is low, a problem is that, in the case where the connection member functions as a series inductor, it is necessary to dispose a filter for preventing an electromagnetic noise, separately from the connector.

The present disclosure is made to solve the above-mentioned problem, and it is therefore an object of the present disclosure to obtain a connector that can prevent an electromagnetic noise without separately disposing a filter, and electronic equipment that employs this connector.

### Solution to Problem

A connector according to the present disclosure connects a first object and a second object, and includes: a first spring structure including a coiled winding, the first spring structure having a first end which is connected to the first object; a second spring structure including a coiled winding which is wound in the same direction as the first spring structure, the second spring structure having a first end which is connected to the second object; a conductor to electrically connect a second end of the first spring structure and a second end of the second spring structure; and a bypass capacitor having a first electrode terminal which is connected to the first spring structure and the conductor, and a second electrode terminal which is grounded, wherein each turn of the winding of the first spring structure and each turn of the winding of the second spring structure are insulated from each other and arranged alternately along the same direction.

### Advantageous Effects of Invention

According to the present disclosure, the first spring structure and the second spring structure connect the first object and the second object, and each turn of the winding of the first spring structure and each turn of the winding of the second spring structure are insulated from each other and arranged alternately along the same direction. As a result, as the mutual inductance formed by the magnetic coupling between the first and second spring structures, a negative inductance occurs equivalently. For example, even though a bypass circuit including a bypass capacitor is disposed in the connector described in Patent Literature 1, a parasitic inductance occurring in the bypass circuit cannot be canceled out because a negative inductance does not occur in the bypass circuit. In the connector according to the present disclosure, because the negative inductance formed by the magnetic coupling between the first and second spring structures cancels out the parasitic inductance occurring in the above-mentioned bypass circuit, an electromagnetic noise can be prevented without separately disposing a filter.

### BRIEF DESCRIPTION OF DRAWINGS

FIG. 1 is a schematic diagram schematically showing the structure of electronic equipment according to Embodiment 1;

FIG. 2 is a circuit diagram schematically showing a mutual induction circuit including a parasitic inductance which occurs in a first spring structure, and a parasitic inductance which occurs in a second spring structure;

FIG. 3 is a circuit diagram showing a T-type equivalent circuit of the mutual induction circuit of FIG. 2;

FIG. 4 is a circuit diagram schematically showing a main part of an equivalent circuit of a connector according to Embodiment 1; and

FIG. 5 is a conceptual diagram schematically showing the structure of electronic equipment according to Embodiment 2.

### DESCRIPTION OF EMBODIMENTS

### Embodiment 1

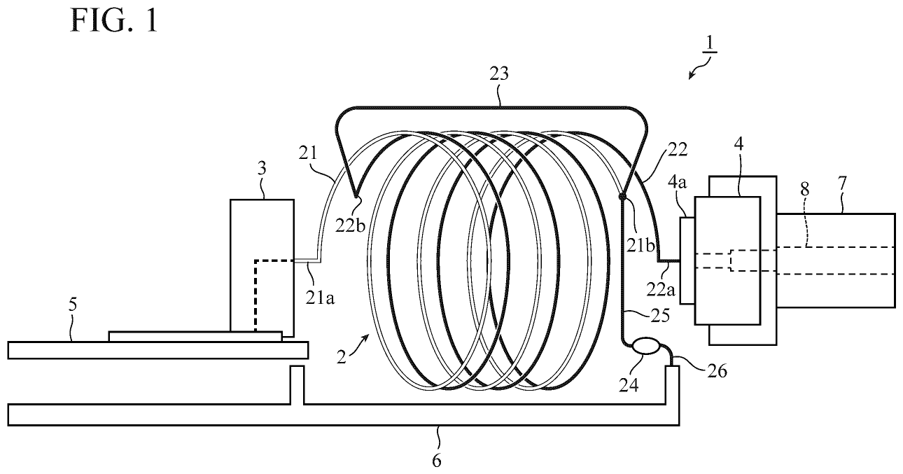

FIG. 1 is a schematic diagram schematically showing the structure of electronic equipment 1 according to Embodiment 1. In FIG. 1, the electronic equipment 1 has a structure in which a connection part 3 and a connection part 4a are connected by a connector 2 according to Embodiment 1. The connection part 3 is a first object which is electrically connected to a printed circuit board 5. The printed circuit board 5 is disposed inside a case 6 of the electronic equipment 1. Further, the case 6 has a constant potential, e.g. a ground potential. The connection part 4a is a second object, such as an electrode terminal, which is disposed in the case 6 of the electronic equipment 1, and a socket 4 is connected to the connection part 4a. The socket 4 is connected to a cable 7. The connection of the socket 4 to the connection part 4a makes an electrical connection of the connection part 4a to a core wire 8 in the cable 7.

The connection between the connection parts 3 and 4a by the connector 2 makes it possible to transmit signals via the connector 2 between the printed circuit board 5 and an external device which is connected to the cable 7.

For example, in the case where the electronic equipment 1 is a high frequency transmitter, the connector 2 functions as a noise filter which removes an electromagnetic noise in a high frequency band which is leaked from a circuit on the printed circuit board 5.

The connector 2 includes a first spring structure 21, a second spring structure 22, a conductor 23, and a bypass capacitor 24, as shown in FIG. 1. The first spring structure 21 includes a coiled winding and has a first end 21a which is connected to the connection part 3. The second spring structure 22 includes a coiled winding which is wound in the same direction as the first spring structure 21, and has a first end 22a which is connected to the connection part 4a.

The first and second spring structures 21 and 22 are constituted by conductors. Although in FIG. 1, the first spring structure 21 is denoted by a white line and the second spring structure 22 is denoted by a black line, the first and second spring structures 21 and 22 are constituted by electrical conduction lines having the same material and the same dimensions.

In the first and second spring structures 21 and 22, their outer edges are insulated from each other in such a way that they are not electrically connected directly to each other. For example, non-conductive tapes are wound around the outer edges of the first and second spring structures 21 and 22.

The conductor 23 electrically connects a second end 21b of the first spring structure 21 and a second end 22b of the second spring structure 22. The first and second spring structures 21 and 22 are connected indirectly by the conductor 23. Although in FIG. 1, the conductor 23 has a bent part, the conductor may be a wiring pattern having a linear shape. Instead, the conductor 23 may be a wiring pattern having a circular or elliptical shape.

The bypass capacitor 24 has a first electrode terminal which is connected to the first spring structure 21 and the conductor 23, and a second electrode terminal which is grounded. For example, the bypass capacitor 24 is connected via a conductor 25 to a point of connection between the second end 21b of the first spring structure 21 and the conductor 23, and is connected via a conductor 26 to the case 6, as shown in FIG. 1. Because the case 6 has a ground potential, the second electrode terminal of the bypass capacitor 24 is grounded. The conductors 25 and 26 may be leading lines of the bypass capacitor 24.

The first and second spring structures 21 and 22 have a coil shape, and are arranged in such a way that the winding axes of the windings are aligned with each other (coaxial). In addition, each turn of the winding of the first spring structure 21 and each turn of the winding of the second spring structure 22 are insulated from each other and arranged alternately along the same direction. The arrangement of the first and second spring structures 21 and 22 in this way forms a mutual inductance through the magnetic coupling between the first and second spring structures. A negative inductance which appears equivalently according to this mutual inductance cancels out a parasitic inductance in the bypass circuit including the bypass capacitor 24.

In addition, because the windings of the first and second spring structures 21 and 22 are arranged alternately at a constant spacing without being distant from each other, the magnetic coupling between them is large compared to that in the case where the structures are distant from each other, and the negative inductance appearing equivalently is also large compared to that in the case where the structures are distant from each other.

The first and second spring structures 21 and 22 have a coil shape in which their windings are wound in the same direction, and are connected in series via the conductor 23. Therefore, currents flow through the first and the second spring structures 21 and 22 in the same direction. Further, magnetic fluxes which occur inside the first and second spring structures 21 and 22, resulting from parasitic inductances, also have the nearly same direction.

In the bypass capacitor 24, a parasitic inductance which causes an electromagnetic noise occurs. Further, in the connector 2, the magnetic coupling between the first and second spring structures 21 and 22 forms a negative inductance. More specifically, the first and second spring structures 21 and 22 are magnetically coupled with each other, so that the first and second spring structures have a pair of parasitic inductances which causes mutual induction. The above-mentioned parasitic inductances occurring in the first and second spring structures 21 and 22 cancel out the parasitic inductance occurring in the bypass capacitor 24. Therefore, the connector 2 can prevent an electromagnetic noise without separately disposing a filter for preventing an electromagnetic noise.

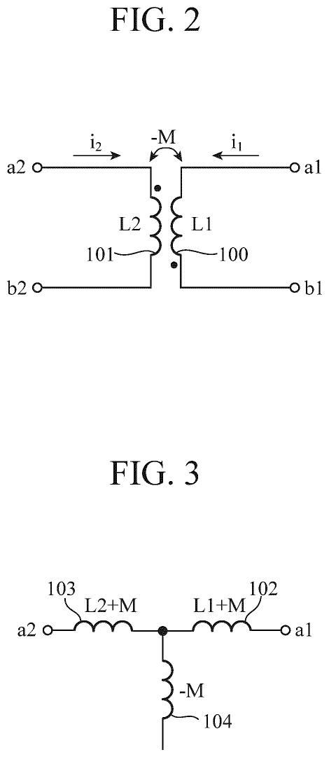

FIG. 2 is a circuit diagram schematically showing a mutual induction circuit including a parasitic inductance 100 occurring in the first spring structure 21, and a parasitic inductance 101 occurring in the second spring structure 22. FIG. 3 is a circuit diagram showing a T-type equivalent circuit of the mutual induction circuit of FIG. 2. In FIGS. 2 and 3, when a current i₁ flows from a node a1 into the parasitic inductance 100 and a current i₂ flows from a node a2 into the parasitic inductance 101, a mutual inductance −M is formed between the parasitic inductances 100 and 101.

In the case where nodes b1 and b2 have a common electric potential, it can be considered that the mutual induction circuit shown in FIG. 2 is the equivalent circuit shown in FIG. 3. The equivalent circuit shown in FIG. 3 includes three inductors 102, 103, and 104 having respective inductances L1+M, L2+M, and −M, and is referred to as a T-type equivalent circuit.

When the number of turns of the first spring structure 21 is N₁, the number of turns of the second spring structure 22 is N₂, the cross-sectional area of the second spring structure 22 is S₂, and the permeability of vacuum is μ₀, the magnitude M of the mutual inductance between the first and second spring structures 21 and 22 can be expressed by the following equation (1).

$$M = {μ}_{0} \times {N}_{1} \times {N}_{2} \times {S}_{2} \qquad ( 1 )$$

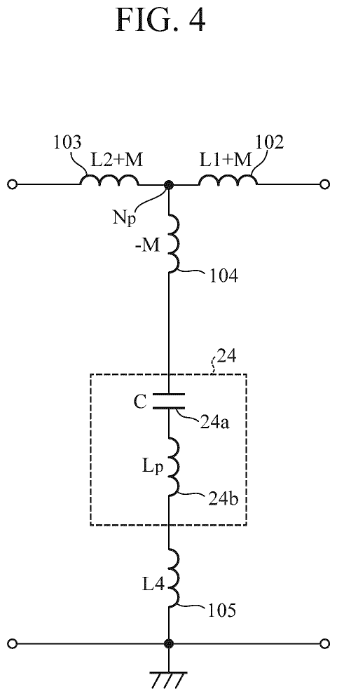

FIG. 4 is a circuit diagram schematically showing a main part of the equivalent circuit of the connector 2. The equivalent circuit shown in FIG. 4 has the T-type equivalent circuit shown in FIG. 3, the bypass capacitor 24, and a parasitic inductance 105 in a wire inductance L4. In FIG. 4, the equivalent inductance of the inductor 102 is L1+M, and the equivalent inductance of the inductor 103 is L2+M.

The bypass capacitor 24 has a capacitor component 24a having a capacitance C, and a parasitic inductance 24b having a residual inductance Lp which is an equivalent series inductance (ESL). The parasitic inductance 105 is formed by the conductors 25 and 26 shown in FIG. 1.

The connector 2 has a bypass circuit including the conductor 25 and the bypass capacitor 24. In this bypass circuit, the first and second spring structures 21 and 22 are magnetically coupled with each other, so that the inductor 104 having the negative inductance −M appears equivalently, as shown in FIG. 4. More specifically, it turns out that the inductor 104 is equivalently connected to a series connection point Np between the inductors 102 and 103.

Further, it turns out that, in the bypass circuit, the inductor 104 having the negative inductance −M, the capacitor component 24a, and the parasitic inductance 24b are connected in series.

The wire inductance L4 can be calculated approximately on the basis of the dimensions of the conductors 25 and 26 (e.g. their lengths and conductor diameters). The residual inductance Lp can be calculated by measuring the characteristics of the bypass capacitor 24.

In the connector 2, the negative inductance −M is designed in such a way that, as to the negative inductance −M, the wire inductance L4, and the residual inductance Lp of the bypass capacitor 24, their impedances cancel one another out. As a result, because the impedance of the bypass circuit becomes equivalent to the impedance of only the capacitor component 24a, design which causes the negative inductance −M to be an optimal value can be performed using the above-mentioned equation (1).

Because in the connector 2, the bypass path in the bypass circuit does not substantially include an inductance component, as mentioned above, reduction in the bypass performance can be prevented even when the frequency of an electromagnetic noise propagating through the spring structures is high.

In order to cancel out the parasitic inductance in the bypass circuit, it can be typically considered that an electronic part, such as an inductor, is added. However, while the addition of a new electronic part causes an increase in the manufacturing cost of the electronic equipment, there is a possibility that a new electronic part electromagnetically acts and adversely affects a wire or an electronic part on the printed circuit board 5.

In contrast with this, the connector 2 can prevent degradation in the bypass performance without adding a new electronic part to the printed circuit board 5. Providing the connector 2 with the noise filtering function in the above-mentioned way eliminates the necessity to mount a noise filter to the printed circuit board 5, implements a reduction in the number of layers of the board and a reduction in the number of parts on the board, and improves the degree of flexibility with which to mount other components.

As mentioned above, the connector 2 according to Embodiment 1 includes: the first spring structure 21 including the coiled winding, and having the first end 21a which is connected to the connection part 3; the second spring structure 22 including the coiled winding which is wound in the same direction as the first spring structure 21, and having the first end 22a which is connected to the connection part 4a; the conductor 23 to electrically connect the second end 21b of the first spring structure 21 and the second end 22b of the second spring structure 22; and the bypass capacitor 24 having the first electrode terminal which is connected to the first spring structure 21 and the conductor, and the second electrode terminal which is grounded, and each turn of the winding of the first spring structure 21 and each turn of the winding of the second spring structure 22 are insulated from each other and arranged alternately along the same direction. As a result, a negative inductance occurs equivalently as the mutual inductance formed by the magnetic coupling between the first and second spring structures 21 and 22. For example, in the case where a bypass circuit including the bypass capacitor 24 is disposed in the connector described in Patent Literature 1, the inductance formed of the series inductor between the connection objects is small, and the parasitic inductance occurring in the bypass circuit cannot be canceled out. Because in the connector 2, the negative inductance formed by the magnetic coupling between the first and second spring structures 21 and 22 cancels out the parasitic inductance occurring in the above-mentioned bypass circuit, an electromagnetic noise can be prevented without separately disposing a filter.

The electronic equipment 1 according to Embodiment 1 includes the connection part 3, the connection part 4a, and the connector 2. Because the connector 2 prevents an electromagnetic noise without disposing a noise filter on the printed circuit board 5, the electronic equipment 1 can be miniaturized.

### Embodiment 2

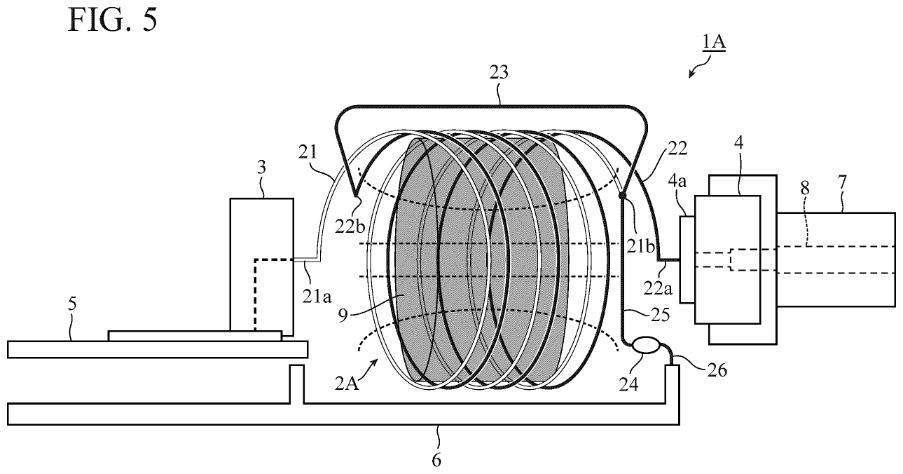

FIG. 5 is a schematic diagram schematically showing the structure of electronic equipment 1A according to Embodiment 2. In FIG. 5, the electronic equipment 1A has a structure in which a connection part 3 and a connection part 4a are connected by a connector 2A according to Embodiment 2. The connection part 3 is a first object which is electrically connected to a printed circuit board 5. The printed circuit board 5 is disposed inside a case 6 of the electronic equipment 1A. Further, the case 6 has a constant potential, e.g. a ground potential.

The connection part 4a is a second object, such as an electrode terminal, which is disposed in the case 6 of the electronic equipment 1A, and a socket 4 is connected to the connection part 4a. The socket 4 is connected to a cable 7. The connection of the socket 4 to the connection part 4a makes an electrical connection of the connection part 4a to a core wire 8 in the cable 7. The connector 2A has a function of preventing an electromagnetic noise, like the connector 2 according to Embodiment 1.

The connector 2A includes a magnetic material 9, a first spring structure 21, a second spring structure 22, a conductor 23, and a bypass capacitor 24, as shown in FIG. 5. The first spring structure 21 includes a coiled winding and has a first end 21a which is connected to the connection part 3. The second spring structure 22 includes a coiled winding which is wound in the same direction as the first spring structure 21, and has a first end 22a which is connected to the connection part 4a.

The magnetic material 9 is disposed inside the first and second spring structures 21 and 22, and is in contact with lower parts of the first and second spring structures 21 and 22, as shown in FIG. 5. As a result, a part of a magnetic path of a magnetic flux which occurs between the first and second spring structures 21 and 22 can be confined inside the magnetic material 9. At this time, a magnetic path through which the magnetic flux MF occurring between the first and second spring structures 21 and 22 passes is formed inside the magnetic material 9, as shown by a broken line in FIG. 5.

By disposing the magnetic material 9 inside the first and second spring structures 21 and 22, the magnetic flux MF can be concentrated to the inside of the magnetic material 9. Therefore, the amount of the magnetic flux which leaks into the air can be reduced. As a result, because the above-mentioned equation (1) is multiplied by the magnetic permeability μᵣ of the magnetic material 9, the magnitude M of the mutual inductance becomes even higher. The cross-sectional area or the number of turns of each spring structure can be set to a value which is smaller by a value corresponding to the increase in the magnitude M of the mutual inductance.

By disposing the magnetic material 9 inside the first and second spring structures 21 and 22, the length of each of the windings of the first and second spring structures 21 and 22 can be shortened, for example. More specifically, the dimensions of the first and second spring structures 21 and 22 which are needed in order to obtain an inductance −M can be reduced.

It is preferable to use a ferrite magnetic material which has high magnetic permeability with respect to high frequency signals of several MHz or higher, as the magnetic material 9. For example, a ferrite core in which soft magnetic metal powder is dispersed may be used as the magnetic material 9.

As mentioned above, the connector 2A according to Embodiment 2 includes the magnetic material 9 which is disposed inside the first and second spring structures 21 and 22. For example, the magnetic material 9 is a ferrite magnetic material. As a result, in the connector 2A, the cross-sectional area or the number of turns of each of the first and second spring structures 21 and 22 can be set to a smaller value. Further, the electronic equipment 1A which can be miniaturized compared to that of Embodiment 1 can be provided.

It is to be understood that a combination of embodiments can be made, a change can be made to an arbitrary component in each of the embodiments, or an arbitrary component in each of the embodiments can be omitted.

### INDUSTRIAL APPLICABILITY

The connector according to the present disclosure can be used in, for example, high frequency transmitters.

### REFERENCE SIGNS LIST

1 and 1A: Electronic equipment, 2 and 2A: Connector, 3 and 4a: Connection part, 4: Socket, 5: Printed circuit board, 6: Case, 7: Cable, 8: Core wire, 9: Magnetic material, 21: First spring structure, 21a, 21b, 22a, and 22b: End, 22: Second spring structure, 23, 25, and 26: Conductor, 24: Bypass capacitor, 24a: Capacitor component, 24b, 100, 101, and 105: Parasitic inductance, 102 to 104: Inductor.

1. A connector that connects a first object and a second object, the connector comprising:
a first spring structure including a coiled winding, the first spring structure having a first end which is connected to the first object;
a second spring structure including a coiled winding which is wound in the same direction as the first spring structure, the second spring structure having a first end which is connected to the second object;
a conductor to electrically connect a second end of the first spring structure and a second end of the second spring structure; and
a bypass capacitor having a first electrode terminal which is connected to the first spring structure and the conductor, and a second electrode terminal which is grounded,
wherein each turn of the winding of the first spring structure and each turn of the winding of the second spring structure are insulated from each other and arranged alternately along the same direction.

2. The connector according to claim 1, wherein the connector includes a magnetic material which is disposed inside the first spring structure and the second spring structure.

3. The connector according to claim 2, wherein the magnetic material is a ferrite magnetic material.

4. Electronic equipment comprising:
the first object;
the second object; and
the connector according to claim 1, to connect the first object and the second object.
